(19) United States
(12) Patent Application Publication
(10) Pub. No.: US 2026/0239695 A1
(43) Pub. Date: Aug. 13, 2026

(54) TRANSISTOR DEVICE AND MANUFACTURING METHOD THEREOF

(71) Applicant: ProAsia Semiconductor Corporation, Hsinchu City (TW)

(72) Inventors: Ming-Chi Kuo, Hsinchu City (TW); I-Tai Li, Hsinchu City (TW)

(21) Appl. No.: 19/279,259

(22) Filed: Jul. 24, 2025

(30) Foreign Application Priority Data
Feb. 7, 2025 (TW) 114104516

(51) Int. Cl. H10D 62/13; H01L 21/223; H10D 30/01; H10D 30/66; H10D 62/832

(52) U.S. Cl. CPC H10D 62/153; H10D 30/0295; H10D 30/662; H10D 62/154; H10D 62/8325; H10P 32/12; H10P 32/171

(57) ABSTRACT

A transistor device and a manufacturing method thereof are provided. The transistor device includes a silicon carbide substrate, a silicon carbide epitaxial layer, a first conductive type doped body region, a second conductive type heavily doped region, a source trench and a first conductive type ion doped interface. The silicon carbide epitaxial layer is disposed on the silicon carbide substrate. The first conductive type doped body region is disposed on the silicon carbide epitaxial layer, the second conductive type heavily doped region is disposed in the first conductive type doped body region, the source trench is disposed in the silicon carbide epitaxial layer and is adjacent to the second conductive type heavily doped region and the first conductive type doped body region, and the first conductive ion doped interface is disposed to surround the sidewall of the source trench.

### CROSS-REFERENCES TO RELATED APPLICATIONS

This application claims the benefit of priority to Taiwanese Patent Application No. 114104516 filed on Feb. 7, 2025, which is hereby incorporated by reference in its entirety.

### BACKGROUND OF THE INVENTION

### Field of the Invention

This invention relates to a transistor device and a manufacturing method thereof, and in particular to a transistor device with improved on-resistance performance and a manufacturing method thereof.

### Descriptions of the Related Art

A Power Metal Oxide Semiconductor Field-Effect Transistor (Power MOSFET), generally referred to as a power transistor, is a field-effect transistor widely used in analog and digital circuits. It has become the mainstream power device, dominating the market and frequently applied in various electronic power applications. Compared to silicon-based power transistors, silicon carbide power transistor devices are used in high-voltage, high-temperature, and low on-resistance high-speed power devices. This is due to the material properties of silicon carbide, which provide a higher breakdown voltage, enabling lower on-resistance with smaller device sizes. Additionally, the higher electron mobility of silicon carbide materials means that silicon carbide power transistor devices have faster switching speeds.

Currently, silicon carbide power transistor devices face the following challenges: (1) The interface between the gate oxide layer and the silicon carbide epitaxial layer is prone to generate defects and lead to high interface trap density (Dit). These defects trap electrons for reducing channel mobility and causing significant reliability issues; (2) Silicon carbide transistors exhibit a higher tunneling effect under a given electric field, resulting in higher leakage current; (3) Silicon carbide substrates are more prone to generate crystal defects compared to silicon substrates, which increases on-resistance (Ron); (4) Conventional techniques to reduce on-resistance involve thinning the silicon carbide substrate. However, the high hardness of silicon carbide makes thinning inefficient and increases process costs. Therefore, improving silicon carbide power transistors to reduce interface trap density, thereby lowering on-resistance and enhancing device voltage withstand capability, is a critical challenge that the industry urgently needs to address.

### SUMMARY OF THE INVENTION

The primary objective of this invention is to provide an innovative transistor device, in particular, to provide a source trench structure in a power transistor device and to perform an implantation of boron ions at a tilt angle into the trench structure. Through diffusion, the boron ions penetrate the silicon carbide epitaxial layer through the sidewall of the source trench, thereby reducing the defect density in the silicon carbide epitaxial layer at the sidewall of the source trench. In particular, a P/N junction is formed between the sidewall of the source trench and the silicon carbide epitaxial layer, improving depletion, increasing the reverse voltage withstand capability of the device, and enhancing on-resistance performance thereof.

To achieve the above objective, this invention provides a transistor device comprising a silicon carbide substrate, a silicon carbide epitaxial layer, a first conductive type doped body region, a second conductive type heavily doped region, a source trench, and a first conductive type ion doped interface. The silicon carbide epitaxial layer is disposed on the silicon carbide substrate. The first conductive type doped body region is disposed on the silicon carbide epitaxial layer. The second conductive type heavily doped region is disposed in the first conductive type doped body region. The source trench is disposed in the silicon carbide epitaxial layer and is adjacent to the second conductive type heavily doped region and the first conductive type doped body region. The first conductive type ion doped interface surrounds the sidewall of the source trench.

In one embodiment of the transistor device of this invention, the first conductive type ion doped interface is a boron ion doped interface with an ion implantation dose of 1E13 to 1E14 cm⁻².

In one embodiment of the transistor device of this invention, the boron ion doped interface has a doping thickness of 1 to 1.5 micrometers (μm).

In one embodiment of the transistor device of this invention, the device further comprises a first conductive type polysilicon layer filled in the source trench.

In one embodiment of the transistor device of this invention, the source trench has a depth of 1 to 10 micrometers (μm).

To achieve the above objective, this invention provides a manufacturing method for a transistor device, comprising: providing a silicon carbide epitaxial layer disposed on a silicon carbide substrate; providing a first conductive type doped body region disposed on the silicon carbide epitaxial layer; providing a second conductive type heavily doped region disposed in the first conductive type doped body region; providing a source trench disposed in the silicon carbide epitaxial layer and adjacent to the second conductive type heavily doped region and the first conductive type doped body region; and providing a first conductive type ion doped interface surrounding the sidewall of the source trench.

In one embodiment of the manufacturing method of the transistor device of this invention, the step of providing a first conductive type ion doped interface is to provide a boron ion doped interface.

In one embodiment of the manufacturing method of the transistor device of this invention, the step of providing a boron ion doped interface is to provide a boron ion implantation with an ion implantation energy of 20 to 100 keV and an ion implantation dose of 1E13 to 1E14 cm⁻².

In one embodiment of the manufacturing method of the transistor device of this invention, the step of providing a boron ion doped interface is to provide a boron ion implantation with a tilt angle of 35° to 45° relative to the vertical normal and a twist angle of 0°.

In one embodiment of the manufacturing method of the transistor device of this invention, the step of providing a boron ion doped interface further comprises, after the step of providing a boron ion implantation, providing a heating step at a temperature of 300 to 1000° C. to diffuse the boron ions into the sidewall of the source trench, thereby forming the boron ion doped interface.

In one embodiment of the manufacturing method of the transistor device of this invention, the step of providing the boron ion doped interface is to form the boron ion doped interface with a doping thickness of 1 to 1.5 micrometers (μm).

In one embodiment of the manufacturing method of the transistor device of this invention, the method further is to provide a first conductive type polysilicon layer filled in the source trench.

In one embodiment of the manufacturing method of the transistor device of this invention, the step of providing a source trench is to provide a source trench with a depth of 1 to 10 micrometers (μm).

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 to FIG. 7 are schematic diagrams illustrating the manufacturing process of a power transistor device in one embodiment of this invention; and

FIG. 8 is a flowchart schematic diagram of the manufacturing process of a power transistor device in one embodiment of this invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

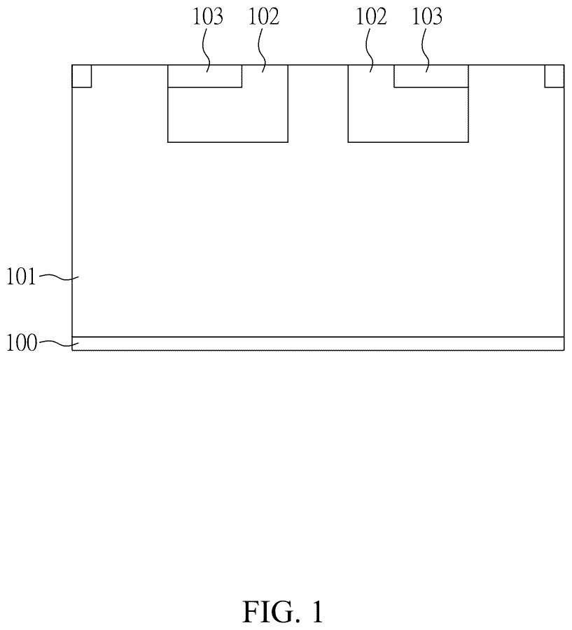

Please refer to FIG. 1 to FIG. 7, which illustrate cross-sectional schematic diagrams of the manufacturing process of a power transistor device in one embodiment of this invention. Specifically, this power transistor device is a Vertical Diffused Metal Oxide Semiconductor Field Effect Transistor (VDMOSFET), as detailed below. The power transistor device includes a silicon carbide substrate 100. Disposed on the silicon carbide substrate 100 is a silicon carbide epitaxial layer 101, which may be, but is not limited to, an N-type lightly doped silicon carbide epitaxial layer with a thickness ranging from a few micrometers (μm) to tens of micrometers (μm) and a low doping concentration of 1E14 to 1E16 cm⁻³, enabling the power transistor device to withstand high voltages. In a specific embodiment, the thickness and doping concentration of the silicon carbide epitaxial layer 101 are designed based on the voltage withstand requirements of the power transistor device.

Next, a plurality of first conductive type doped body regions 102 are formed on the silicon carbide epitaxial layer 101. Specifically, each first conductive type doped body region 102 may be a P-type lightly doped body region with a doping concentration of 1E16 to 1E17 cm⁻³, which falls within a medium to low doping concentration range. This ensures that the transistor device has sufficient blocking capability in the off state while providing a controllable channel region. Additionally, since the power transistor device in this embodiment is a vertical diffused metal oxide semiconductor field effect transistor, each first conductive type doped body region 102 further includes at least one second conductive type heavily doped region 103 disposed above the first conductive type doped body region 102 near the side edge of the transistor device's surface. Specifically, this second conductive type heavily doped region 103 may be an N-type heavily doped region with a doping concentration in the range of 1E19 to 1E20 cm⁻³, ensuring low resistance to serve as the source region of the power transistor device and forming a good ohmic contact with the source metal.

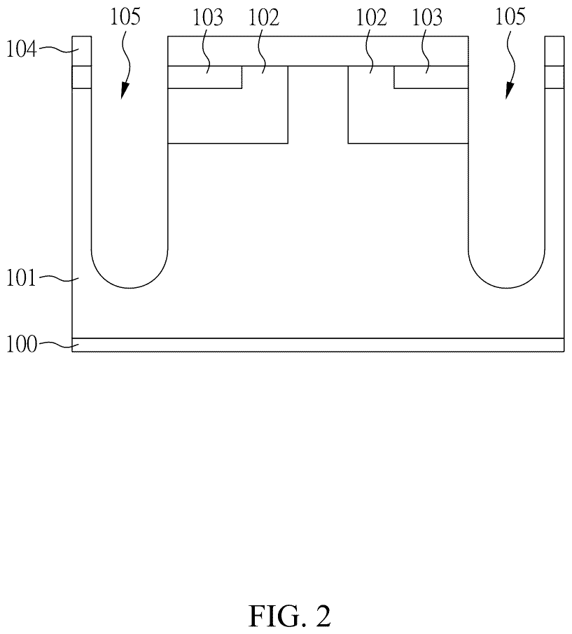

Please refer to FIG. 2, which illustrates forming a patterned photoresist 104 on the device surface to define the pattern of the source trench structure. Next, the silicon carbide epitaxial layer 101 is etched using the patterned photoresist 104 as an etching mask, forming a trench structure 105 in the silicon carbide epitaxial layer 101. The sidewall of the trench structure 105 is disposed adjacent to the first conductive type doped body region 102 and the second conductive type heavily doped region 103 on the silicon carbide epitaxial layer 101. This trench structure 105 forms part of a deep source trench, with its depth related to the high-voltage specifications of the power transistor device. Generally, the trench structure 105, serving as the source, has a depth of 1 to 10 micrometers (μm) and an inner diameter width of 1 to 3 micrometers (μm), enabling the power transistor device to withstand high voltages of up to 3000 volts. Preferably, the trench structure 105 has a depth of 1 to 5 micrometers (μm).

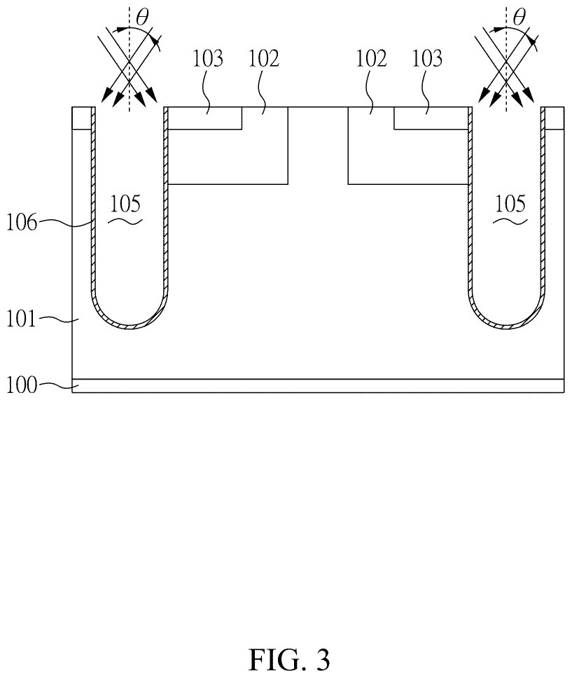

Next, as shown in FIG. 3, a first conductive type tilt ion implantation is performed on the sidewall of the trench structure 105. Specifically, the first conductive type tilt ion implantation has a tilt angle (θ) relative to the vertical normal, with the tilt angle θ ranging from 35° to 45°, and a twist angle of 0°. On the other hand, in a specific embodiment, the first conductive type tilt ion implantation is performed using P-type ions, such as boron (B) ions, with a doping dose per unit area of 1E13 to 1E14 cm⁻² and a doping energy of 20 to 100 keV, implanting first conductive type ions 106 into the sidewall surface of the trench structure 105.

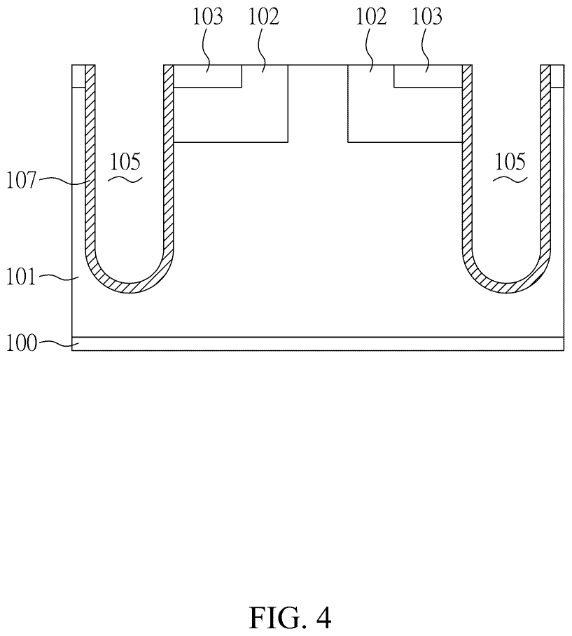

Next, please refer to FIG. 4, where a heating process is performed, raising the temperature to 300 to 1000° C., allowing the first conductive type ions 106 to diffuse into the silicon carbide epitaxial layer 101 adjacent to the sidewall of the trench structure. This forms a first conductive type ion doped interface 107 between the sidewall of the trench structure and the silicon carbide epitaxial layer 101. It should be noted that this interface is a P/N junction formed between the first conductive type ions and the second conductive type lightly doped silicon carbide epitaxial layer. Specifically, the boron ions in this interface capture defects in the P/N junction, reducing the defect density and improving the interface, thereby enhancing depletion, increasing reverse voltage withstand capability, and improving Ron performance. In a preferred embodiment, this boron ion doped interface has a doping thickness of 1 to 1.5 micrometers (μm).

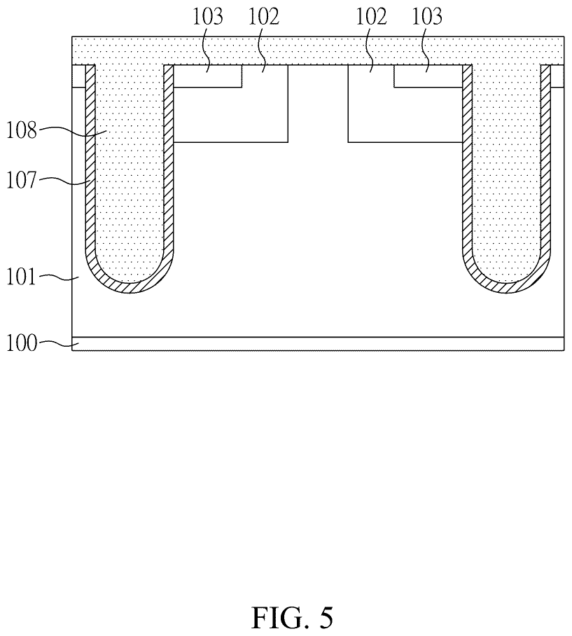

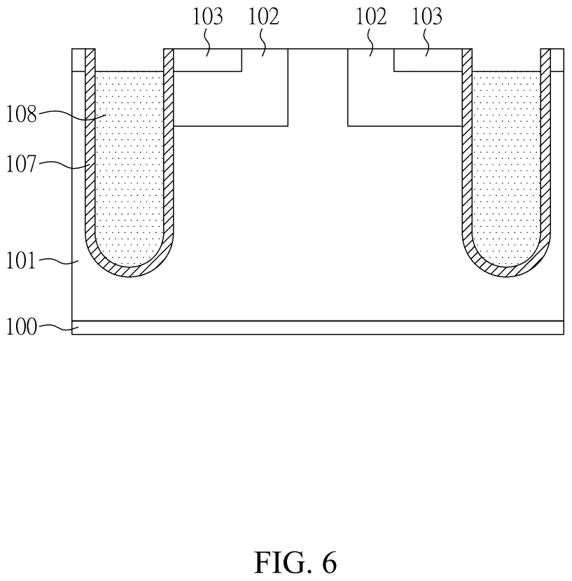

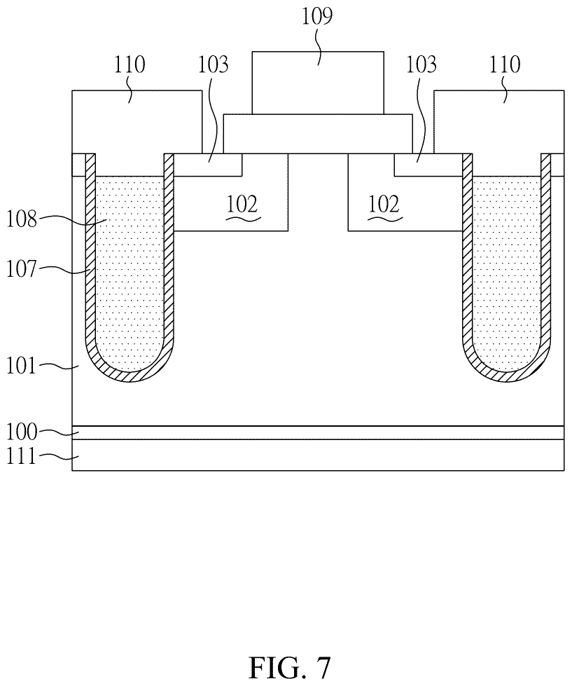

Please continue to refer to FIG. 5, where a first conductive type polysilicon 108 is filled into the trench structure, covering the device surface by approximately 1 to 2 micrometers (μm). In a specific embodiment, the first conductive type polysilicon material is P-type polysilicon material. Additionally, besides the first conductive type polysilicon material, metals (such as tungsten or titanium nitride) or a composite stack of metal and polysilicon may also be filled into the trench structure. Next, a patterned etching process is performed to remove excess first conductive type polysilicon 108, and the first conductive type polysilicon 108 in the trench structure is etched back to a certain height, completing the source trench structure, as shown in FIG. 6. Finally, a metallization process is performed, as shown in FIG. 7, forming a gate metal 109, a source metal 110, and a drain metal 111 on the transistor device to complete the metal contact processes for the gate region, source region, and backside drain region.

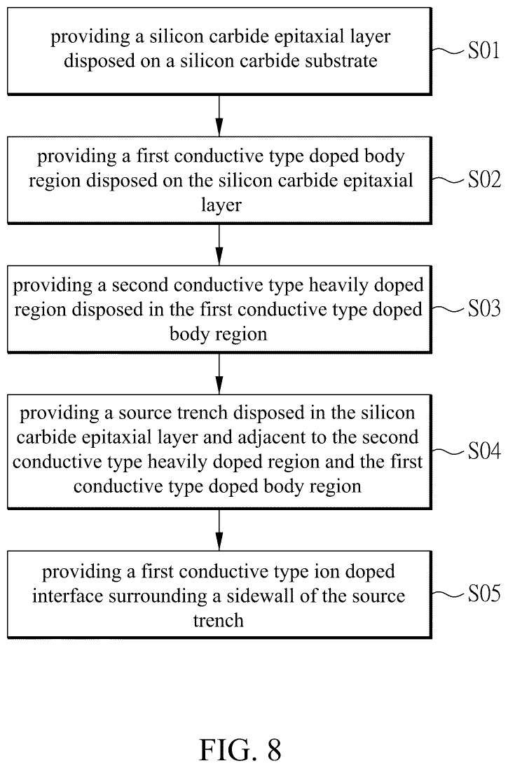

Please refer to FIG. 8, which illustrates a flowchart schematic diagram of the manufacturing process of the power transistor device of this invention. First, in step S01, a silicon carbide epitaxial layer is provided, disposed on a silicon carbide substrate. In step S02, a first conductive type doped body region is provided, disposed on the silicon carbide epitaxial layer. Next, in step S03, a second conductive type heavily doped region is provided, disposed in the first conductive type doped body region. In step S04, a source trench is provided, disposed in the silicon carbide epitaxial layer and adjacent to the second conductive type heavily doped region and the first conductive type doped body region. In step S05, a first conductive type ion doped interface is provided, surrounding the sidewall of the source trench. The descriptions of the related components in the aforementioned process steps can be referred to the above content and will not be repeated here.

The above embodiments are provided to illustrate the implementations of the present invention and to explain its technical features, and are not intended to limit the scope of the present invention. Any modifications or equivalent arrangements that can be easily accomplished by those skilled in the art fall within the scope of the present invention, and the scope of the present invention should be defined by the claims.

What is claimed is:

1. A transistor device, comprising:
a silicon carbide substrate;
a silicon carbide epitaxial layer disposed on the silicon carbide substrate;
a first conductive type doped body region disposed on the silicon carbide epitaxial layer;
a second conductive type heavily doped region disposed in the first conductive type doped body region;
a source trench disposed in the silicon carbide epitaxial layer and adjacent to the second conductive type heavily doped region and the first conductive type doped body region; and
a first conductive type ion doped interface surrounding a sidewall of the source trench.

2. The transistor device of claim 1, wherein the first conductive type ion doped interface is a boron ion doped interface with an ion implantation dose of 1E13 to 1E14 cm⁻².

3. The transistor device of claim 2, wherein the boron ion doped interface has a doping thickness of 1 to 1.5 micrometers (μm).

4. The transistor device of claim 1, further comprising a first conductive type polysilicon layer filled in the source trench.

5. The transistor device of claim 1, wherein the source trench has a depth of 1 to 10 micrometers (μm).

6. A manufacturing method of a transistor device, comprising:
providing a silicon carbide epitaxial layer disposed on a silicon carbide substrate;
providing a first conductive type doped body region disposed on the silicon carbide epitaxial layer;
providing a second conductive type heavily doped region disposed in the first conductive type doped body region;
providing a source trench disposed in the silicon carbide epitaxial layer and adjacent to the second conductive type heavily doped region and the first conductive type doped body region; and
providing a first conductive type ion doped interface surrounding a sidewall of the source trench.

7. The manufacturing method for a transistor device of claim 6, wherein the step of providing a first conductive type ion doped interface is to provide a boron ion doped interface.

8. The manufacturing method for a transistor device of claim 7, wherein the step of providing a boron ion doped interface is to provide a boron ion implantation with an ion implantation energy of 20 to 100 keV and an ion implantation dose of 1E13 to 1E14 cm⁻².

9. The manufacturing method for a transistor device of claim 7, wherein the step of providing a boron ion doped interface is to provide a boron ion implantation with a tilt angle of 35° to 45° relative to a vertical normal and a twist angle of 0°.

10. The manufacturing method for a transistor device of claim 7, wherein the step of providing a boron ion doped interface further comprises, after the step of providing a boron ion implantation, providing a heating step at a temperature of 300 to 1000° C. to diffuse the boron ions into the sidewall of the source trench for forming the boron ion doped interface.

11. The manufacturing method for a transistor device of claim 10, wherein the step of providing the boron ion doped interface is to form the boron ion doped interface with a doping thickness of 1 to 1.5 micrometers (μm).

12. The manufacturing method for a transistor device of claim 6, further comprising providing a first conductive type polysilicon layer filled in the source trench.

13. The manufacturing method for a transistor device of claim 6, wherein the step of providing a source trench is to provide a source trench with a depth of 1 to 10 micrometers (μm).
